(19) United States
(12) Patent Application Publication
(10) Pub. No.: US 2020/0144452 A1
(43) Pub. Date: May 7, 2020

(54) SURFACE LIGHT-EMITTING LED

(71) Applicant: Dongguan Ekinglux Optoelectronic Technology Co. LTD., Dongguan (CN)

(72) Inventor: Jun LU, Dongguan (CN)

(21) Appl. No.: 16/396,750

(22) Filed: Apr. 28, 2019

(30) Foreign Application Priority Data
Nov. 7, 2018 (CN) 201811321535.3

(51) Int. Cl. H01L 33/36; H01L 33/24; H01L 33/26

(52) U.S. Cl. CPC H01L 33/36; H01L 33/26; H01L 33/24

(57) ABSTRACT

A surface light-emitting LED, including an LED chip and a metal support. The metal support includes a first support and a second support in planar shapes. The LED chip is fixed to the second support, and two electrodes of the LED chip are respectively connected to the first support and the second support by wires. An epoxy layer is provided on the first support and the second support. A gap between the first support and the second support is filled with the epoxy layer. The LED of the present invention emits light in all directions, improving illumination of the LED.

### CROSS-REFERENCE TO RELATED APPLICATIONS

This application claims the benefit of priority from Chinese Patent Application No. CN201811321535.3, filed on Nov. 7, 2018. The content of the aforementioned application, including any intervening amendments thereto, is incorporated herein by reference in its entirety.

### TECHNICAL FIELD

The present disclosure relates to light emitting diodes (LEDs), and in particular to surface light-emitting LEDs.

### BACKGROUND OF THE INVENTION

LED light strips or strings are used in a wide range of applications. SMD LED for the light string (or “light strip”) is usually provided with a BT (Bismaleimide triazine) plate at the bottom. However, the LED light string can only emit light at 180 degrees on the front side, and a big shadow on the bottom of the back side of the LED occurs due to the substrate, thus affecting the illumination of the LED light strip. The conventional LED is made by means of die bond, wire soldering and pouring sealant on PCB to illuminate the front side. There is a need to develop an LED with through holes formed on a support, in which the light emitted by the die may be refracted to the back side through the through holes to form a surface illumination or 360° illumination. Thus, the LED gives out light from front and back sides and side surfaces thereof. Accordingly, illumination of the light string using such LED is improved.

Therefore, the prior art still needs to be improved.

### SUMMARY OF THE INVENTION

In view of above defects in the prior art, the present invention provides a surface light-emitting LED to overcome the problem that an SMD LED can only emit light within 180 degrees.

A surface light-emitting LED includes an LED chip and a metal support; wherein the metal support includes a first support and a second support in planar shapes; the LED chip is fixed to the second support; two electrodes of the LED chip are respectively connected to the first support and the second support by wires; an epoxy layer is provided on the first support and the second support; and a gap between the first support and the second support is filled with the epoxy layer.

A first through hole is provided on the first support, and a second through hole is provided on the second support. The first through hole and the second through hole are filled with the epoxy layer.

The first support and the second support are equal in thickness and width.

A length of the metal support is 1.4-2 mm, a width of the metal support is 0.7-1.2 mm, and a height of the metal support is 0.1-0.25 mm.

The epoxy layer has an upper surface in a planar or curved shape.

A thickness of the epoxy layer is 0.4-0.8 mm.

The first support and the second support each are integrally formed by stamping.

Beneficial Effects:

As compared to the prior art, the surface light-emitting LED of the invention is provided with light transmission areas in the metal support of the LED, and the use of substrate connected to the bottom of the metal support are eliminated. Therefore, the LED can also emit light on the back side. Thus, the LED emits light in all directions, improving the illumination of the LED.

### BRIEF DESCRIPTION OF THE DRAWINGS

FIG. 1 is a top view of a surface light-emitting LED of the present invention.

FIG. 2 is a bottom view of the surface light-emitting LED of the present invention.

FIG. 3 is a sectional view taken along A-A in FIG. 1.

### DETAILED DESCRIPTION OF EMBODIMENTS

The present invention relates to a surface light-emitting LED. The present invention will be further described in details with reference to the accompanying drawings and embodiments, from which the features of the present invention become more apparent and clearer. It is understood that the specific embodiments described herein are merely illustrative of the invention and are not intended to limit the invention.

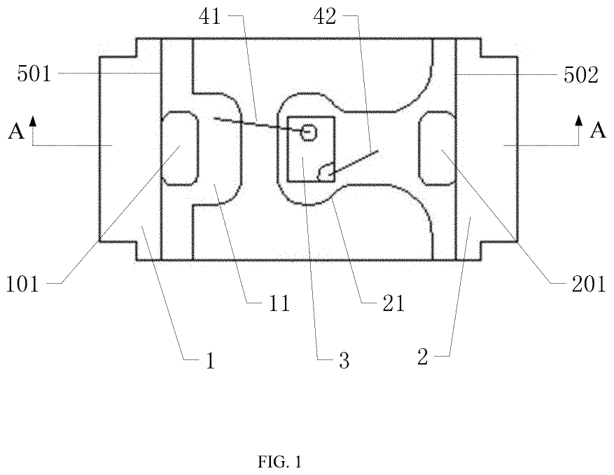

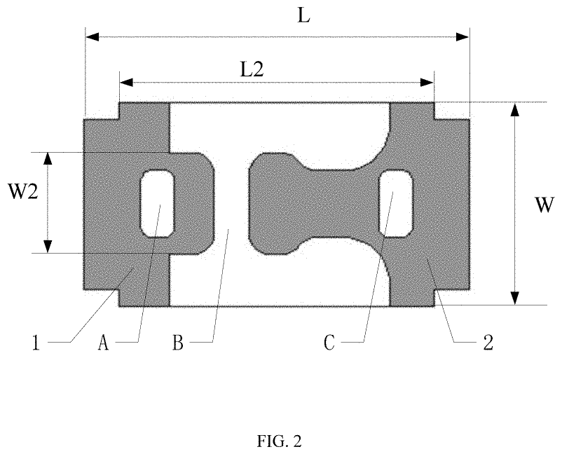

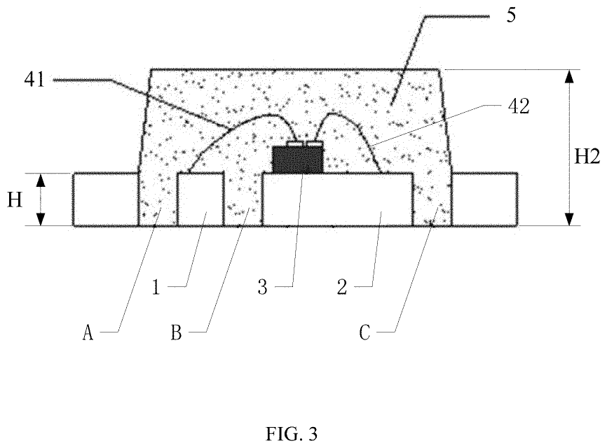

As shown in FIGS. 1-3, the present invention provides a surface light-emitting LED. Straight lines 501 and 502 in FIG. 1 indicate borders of two ends of a transparent glue layer; a metal support is indicated by a black fill in FIG. 2, and wires 41 are not indicated in FIG. 2 and FIG. 3.

The surface light-emitting LED includes an LED chip 3 and a metal support; the metal support includes a first support 1 and a second support 2 in planar shapes; the LED chip 3 is fixed to the second support 2; two electrodes of the LED chip are respectively connected to the first support 1 and the second support 2 by wires (including a wire 41 and a wire 42); an epoxy layer 5 is provided on the first support and the second support; and a gap between the first support 1 and the second support 2 is filled with the epoxy layer 5. The “planar shape” indicates that all the upper and lower surfaces of the first support and the second support are in planar shapes; the wire may be a gold wire, an alloy wire or a copper wire, which is not limited herein. The metal support is usually made of copper or aluminium.

It should be noted that fluorescent powder (it is not drawn in drawings) is provided on the surface light-emitting LED to realize a certain color of the LED in practical use. The fluorescent powder is not limited herein because the specific light color is not unimportant in the present invention. The preferred shapes of the first support and the second support are as shown in FIG. 1 and FIG. 2. Namely, a first pad 11 on the first support and a second pad 21 on the second support opposite to each other but not in contact are provided. The LED chip is connected to the first pad by wire 41. The LED chip is connected to the second pad by wire 42. A width W2 of the first pad or the second pad is less than the width W of the metal support, so that there is a larger light transmission area between the first support and the second support.

Preferably, a first through hole 101 is provided on the first support 1, and a second through hole 201 is provided on the second support 2. The first through hole and the second through hole are filled with the epoxy layer. By providing the first through hole and the second through hole, the light transmission area is increased and the light transmission on the back side is improved.

Preferably, in order to simplify the machining process, the first support 1 and the second support 2 are equal in thickness and width. Namely, the width of the first support or the second support is equal to the width W of the metal support.

Preferably, a length L of the metal support is 1.4-2 mm, a width W1 of the metal support is 0.7-1.2 mm, and a thickness H of the metal support is 0.1-0.25 mm.

Preferably, the epoxy layer 5 has an upper surface in a planar or curved shape. The epoxy layer has an upper surface in a planar or curved shape in FIG. 3, but it is not limited to the planar shape.

Preferably, a thickness H2 of the epoxy layer is 0.4-0.8 mm.

Preferably, as shown in drawings, a length L2 of the epoxy layer is less than a length L1 of the metal support, namely, ends of the metal support are exposed from ends of the epoxy layer to form pins; and the lower surfaces of the epoxy layer and the metal support are at a same level.

Preferably, the first support 1 and the second support 2 each are integrally formed by stamping.

The principle of surface light-emitting will be briefly described hereinafter. The first support and the second support are respectively used as an anode and a cathode of the LED to connect with an external input circuit (no shown). The first support and the second support are fixed by coating with the epoxy layer, thus eliminating the use of BT plate in the prior art. As shown in FIGS. 2 and 3, three light transmission areas including A (the first through hole), B (the area between the first support and the second support) and C (the second through hole) are formed in the metal support. The three light transmission areas are filled with the epoxy layer which is transparent, so that light is transmitted through the above three light transmission areas. The LED can not only illuminate the front and two sides, and it can also illuminate the back side because the light reflected by the epoxy layer can penetrate through the three light transmission areas, namely, light is emitted from all directions to realize 360° illumination, improving the illumination of the LED.

It can be seen from the above, compared with the SMD LED in the prior art, the light transmission areas are provided in the metal support of the surface light-emitting LED of the present invention, and no substrate is connected to the bottom of the metal support. Therefore, the LED can also illuminate the back side, and the LED give out light in all directions, improving the illumination effect of the LED. The LED of the present invention can also be made into light strips and can be widely used in light strips, stage lights, toys and decorations.

It should be understood that those skilled in the art can make any equivalent substitutions or changes in accordance with the features or spirit of the present invention, and such changes or substitutions should fall within the scope of the present invention.

What is claimed is:

1. A surface light-emitting LED, comprising:
an LED chip, and
a metal support;
wherein the metal support comprises a first support and a second support in planar shapes; the LED chip is fixed to the second support; two electrodes of the LED chip are respectively connected to the first support and the second support through wires; an epoxy layer is provided on the first support and the second support; and a gap between the first support and the second support is filled with the epoxy layer.

2. The surface light-emitting LED of claim 1, wherein a first through hole is provided on the first support, and a second through hole is provided on the second support; and the first through hole and the second through hole are filled with the epoxy layer.

3. The surface light-emitting LED of claim 2, wherein the first support and the second support are equal in thickness and width.

4. The surface light-emitting LED of claim 3, wherein a length of the metal support is 1.4-2 mm, a width of the metal support is 0.7-1.2 mm, and a thickness of the metal support is 0.1-0.25 mm.

5. The surface light-emitting LED of claim 3, wherein the epoxy layer has an upper surface in a planar or curved shape.

6. The surface light-emitting LED of claim 5, wherein a thickness of the epoxy layer is 0.4-0.8 mm.

7. The surface light-emitting LED of claim 1, wherein the first support and the second support each are integrally formed by stamping.
